(19) United States
(12) Patent Application Publication
(10) Pub. No.: US 2006/0162767 A1
(43) Pub. Date: Jul. 27, 2006

(54) Multi-junction, monolithic solar cell with active silicon substrate

(76) Inventors: Angelo Mascarenhas, Lakewood, CO (US); Maeng-Je Seong, Lakewood, CO (US)

Correspondence Address: Paul J White;National Renewable Energy Laboratory, 1617 Cole Boulevard, Golden, CO, 80401, US

(21) Appl. No.: 10/523,745

(22) PCT Filed: Aug. 16, 2002
(86) PCT No.: PCT/US02/26958

§ 371 Date: Feb. 3, 2005

(51) Int. Cl. H01L 31/00

(52) U.S. Cl. 136/261; 136/249; 136/255

(57) ABSTRACT

A monolithic multi-junction (tandem) photo-voltaic (PV) device includes one or more PV subcells epitaxially formed on a compliant silicon substrate (102). The compliant silicon substrate (102) includes a base silicon layer (108), a conductive perovskite layer (112), and an oxide layer (110) interposed between the base silicon layer (108) and the conductive perovskite layer (112). A PV subcell is formed within the base silicon layer (108) of the conductive silicon substrate (102). The conductive perovskite layer (112) facilitates the conduction of charge carriers between the PV subcell formed in the compliant silicon substrate (102) and the one or more PV subcells formed on the compliant silicon substrate (102).

### CONTRACTUAL ORIGIN OF THE INVENTION

The United States Government has rights in this invention under Contract No. DE-AC36-99GO10337 between the United States Department of Energy and the National Renewable Energy Laboratory, a Division of the Midwest Research Institute.

### TECHNICAL FIELD

The present invention relates generally to energy conversion devices, and more particularly to series-connected, monolithic tandem PV cells having one or more PV subcells formed on a compliant silicon substrate, wherein the compliant silicon substrate includes a PV subcell formed therein.

### BACKGROUND ART

Solar energy represents a vast source of non-polluting, harnessable energy. It is estimated that the amount of solar energy striking the United States each year far exceeds the country's energy needs for that year. Despite this abundance, solar energy has proven difficult to economically collect, store, and transport, and, thus has been relatively overlooked compared to the other more conventional energy sources, i.e., oil, gas and coal. However, as conventional energy sources become less abundant, and their detrimental effect on the environment continues to escalate (acid rain, air particulates, green house gasses, etc), solar energy is becoming a more viable and attractive energy source.

One of the more effective ways of harnessing solar energy is through photovoltaic (PV) cells, which convert solar energy directly into electrical energy. The conversion of radiant energy, e.g., solar energy, into electrical energy by PV cells relies on p-type and n-type conductivity regions in semiconductor materials. These regions generate a voltage potential and/or current when electron-hole pairs are created in the semiconductor material in response to impinging photons in the PV cell. The amount of energy required to liberate an electron in a semiconductor material is known as the material's band-gap energy. Different PV semiconductor materials have different characteristic band-gap energies. For example, semiconductor materials used in a PV cell typically have band-gap energies that range from 1.0 eV to 1.9 eV, corresponding to the energy of solar photons. To maximize the amount of radiant energy absorbed by a PV cell, multi-layered or multi-subcell PV cells have been developed to absorb a wider spectrum of solar energy.

Multi-subcell PV cells generally include stacks of multiple semiconductor layers or PV subcells grown upon a substrate. Preferably, each PV subcell in a PV subcell stack is composed of a semiconductor material having a band-gap energy designed to convert a different solar energy level or wavelength range to electricity. The subcell within the PV cell that receives the radiant energy first has the highest band-gap energy, and subcells having correspondingly smaller band-gap energies are ordered/positioned below. Thus, radiant energy in a wavelength not absorbed and converted to electrical energy at the first subcell, having the largest band-gap energy in the PV cell, may be captured and converted to electrical energy at a second subcell, having a band-gap energy smaller than the band-gap energy of the first subcell. In this manner, a broad spectrum of input radiant energy can be converted to electrical energy, providing the PV cell with adequate efficiency for converting input radiant energy into electrical energy.

Typically, the PV subcells in a multi-subcell PV cells are connected in series and are current matched to increase photocurrent levels within the PV cell. Current matching can be controlled during fabrication of the PV cell by selecting and controlling the relative band-gap energy of the various semiconductor materials used to form the p-n junctions within each subcell, and/or by altering the thickness of each subcell to modify its resistance. To improve current flow between PV subcells in a multi-subcell PV cell a low-resistivity tunnel junction layer is typically inserted between any two current matched subcells.

Although there are multiple ways of fabricating a multi-subcell PV cell, it is preferable to grow the PV cell as a monolithic crystal upon a base or substrate. Non-monolithic PV cells require the mechanical alignment and adhesion between different subcells in the cell, a process that is time consuming, costly and can lead to positional errors not evident in monolithic cells. As such, a current goal of the PV field is to fabricate monolithic PV cells.

A limitation in designing multi-junction, monolithic PV cells, particularly PV cells having layers formed from Group III-V direct band-gap semiconductor materials, is the desire for lattice matching between adjacently stacked layers of semiconductor materials that make-up the multi-subcells of the PV cell. Lattice mismatching between adjacent layers of a PV cell results in strain and dislocations to form, thereby reducing the overall efficiency of the PV cell to convert radiant energy into electrical energy. As such, semiconductor materials used to fabricate monolithic, multi-subcell PV cells will optimally have matched lattice constants. However, there is a limited selection of known Group III-V direct band-gap semiconductor materials having the requisite band-gap energies for use in a PV cell, and of these only a few can be lattice matched to form a monolithic PV cell.

Lattice matching limitations between Group III-V direct band-gap semiconductor materials is further exacerbated by the fact that the PV subcell semiconductor material is grown on a substrate template, where the substrate has its own, and ultimately limiting, lattice constant that must be matched. As such, the design of monolithic PV cells using Group III-V semiconductor materials are typically limited to a set of defined substrate/semiconductor materials having matched lattice constants and appropriate band-gap energy for the intended use. Typically, gallium arsenide (GaAs), indium phosphide (InP), and germanium (Ge) have been the most commonly used as templates in growing multi-subcell, monolithic PV cells employing Group III-V direct band-gap semiconductor materials. Noticeably absent from this list of commonly used substrates is silicon. While silicon would be an ideal substrate in terms of durability and expense for use in PV cells, silicon has a lattice constant that is incompatible with most Group III-V direct band-gap semiconductor materials. Note also that silicon, when properly doped to have a junction, has the potential of being a 1.1 eV subcell, ideal for many PV cell applications.

Recently, fabrication methods have been developed that allow the growth of Group III-V direct band-gap materials on what is referred to as a “compliant silicon substrate.” A compliant silicon substrate typically includes a base silicon layer, an intermediary oxide of the silicon base layer, and a perovskite layer, such as Strontium Titanate (STO), deposited thereon. The oxide layer results in interfacial stress relief at the perovskite layer, thereby resulting in the compliant substrate having a “flexible” lattice constant that can accommodate the growth of a wide range of subsequent semiconductor materials, including Group III-V direct band-gap materials.

While a compliant substrate will accommodate the growth of Group III-V direct band-gap materials thereon, a compliant substrate has not previously been used in the fabrication of multi-subcell PV cells, where a PV subcell is formed within the compliant substrate and is series-connected to the other PV subcells in the PV subcell stack, such as with a tunnel junction. One obstacle to fabrication and design of such series-connected multi-subcell PV cells is that the STO layer acts as an electric insulator blocking the flow of charge carriers between the silicon base layer and the PV subcell(s) formed on the compliant substrate.

Against this backdrop the present invention has been developed.

### SUMMARY OF THE INVENTION

The present invention provides monolithic photovoltaic (PV) cells and devices for converting radiant energy to electrical energy. More particularly, the present invention relates to series-connected, monolithic tandem PV cells having one or more PV subcells formed on a compliant silicon substrate, wherein the compliant silicon substrate includes a PV subcell formed therein.

In accordance with a first embodiment of the present invention, a two-subcell PV cell includes a compliant silicon substrate having a first PV subcell formed therein, upon which is epitaxially grown a second PV subcell. In this embodiment, the second PV subcell is formed of a Group III-V direct bandgap semiconductor material having a lattice constant that is flexibly accommodated by the compliant silicon substrate. The compliant silicon substrate includes a silicon base layer, a conductive perovskite layer, and a Silicon Dioxide (SiO₂) layer formed between the silicon base layer and the conductive perovskite layer. In this embodiment, the first PV subcell is formed within the base silicon layer and the conductive perovskite layer allows for the conduction of charge carriers between the first and second PV subcells.

In accordance with a second embodiment of the present invention, a three-subcell PV cell includes a compliant silicon substrate, having a first PV subcell formed therein, a second PV subcell formed on top of the compliant silicon substrate, and a third PV subcell formed on top of the second PV subcell. In accordance with this second embodiment, the second and third PV subcells are epitaxilly grown on top of the compliant silicon substrate. In this embodiment, both the second PV subcell and the third PV subcell are formed of a Group III-V direct bandgap semiconductor materials having lattice constants that are flexibly accommodated by the compliant silicon substrate. The compliant silicon substrate includes a silicon base layer, a conductive perovskite layer, and a Silicon Dioxide (SiO₂) layer formed between the silicon base layer and the conductive perovskite layer. In this embodiment, the first PV subcell is formed within the base silicon layer and the conductive perovskite layer allows for the conduction of charge carriers between the first, second, and third PV subcells.

These and various other features as well as advantages which characterize the present invention will be apparent from a reading of the following detailed description and a review of the associated drawings.

### BRIEF DESCRIPTION OF THE DRAWINGS

FIG. 1 illustrates a generalized multi-PV cell, tandem monolithic photovoltaic (PV) device in accordance the present invention.

FIG. 2 illustrates a two-PV cell, tandem monolithic photovoltaic (PV) device 300 in accordance with a second embodiment of the present invention

FIG. 3 illustrates a three-PV cell, tandem monolithic photovoltaic (PV) device in accordance with an embodiment of the present invention.

### DETAILED DESCRIPTION OF THE INVENTION

In general, various embodiments of the present invention relate to monolithic multi-junction (tandem) photovoltaic (PV) devices. More particularly, various embodiments of the present invention relate to series-connected, monolithic tandem PV cells having one or more PV subcells formed on a compliant silicon substrate, wherein the compliant silicon substrate includes a PV subcell formed therein. In these various embodiments, the compliant silicon substrate includes a base silicon layer, a silicon dioxide (SiO₂) layer, and an electrically conductive perovskite layer, where the electrically conductive perovskite layer and the SiO₂ layer functions to physically and electrically connect the PV subcell in the silicon base to the other PV subcells in the PV cell.

Each of the various PV cells described herein comprises a “stack” of PV subcells in what is commonly referred to as lattice-matched, monolithic, multi-junction or tandem PV cell. As is known, monolithic, multi-junction PV cells are typically fabricated using a process wherein various layers of crystalline semiconductor material are epitaxially deposited (i.e., grown) on a substrate to form a stack of PV subcells, which together form a single crystallographic structure (i.e., monolithic). As is also known, a “coherently lattice-matched” PV cell refers to a PV cell wherein the various layers of crystalline semiconductor material in the cell have lattice constants that are similar enough to one another that when the materials are grown adjacent to each other epitaxially the difference or mismatch between lattice constants of the materials is resolved by elastic deformation and not by inelastic relaxation.

As described in greater detail below, each of the individual PV subcells in the various PV cells described herein is preferably composed of a semiconductor compound or alloy formed from elements selected from the third and fifth column of the Periodic Table of Elements (Group III-V materials). Additionally, each of the individual PV subcells in the various PV cells described herein preferably includes a doped n-type region, a doped p-type region, and a p-n or n-p junction between the subcells, to form a PV subcell operable to produce electrical energy via the photoelectric effect when the cell absorbs photons, such as from sunlight. Similarly, the compliant silicon substrate in each of the various PV cells described herein also includes a doped n-type region, a doped p-type region, and a p-n or n-p junction between the subcells, to form a PV subcell operable to produce electrical energy via the photoelectric effect when the cell absorbs photons.

As is known, each type of semiconductor material has a particular characteristic band-gap energy. As such, PV subcells formed of semiconductor materials may be referred to as having a particular band-gap energy. As is also known, a PV subcell will absorb, and convert to electrical energy, photons with energies greater than the band-gap energy of the PV subcell. When a PV subcell is exposed to radiant energy having photons with a wide range of energy levels, such as the sun, only those photons having energy levels greater than or equal to the band-gap energy of the PV subcell will make a contribution to the electrical energy output from the PV subcell. Conversely, those photons in the radiant energy having energy levels less than the band-gap energy of the PV subcell will make no contribution to the electrical energy output from the PV subcell. As such, the energy contained in the photons having energy levels less than the band-gap energy of the PV subcell is wasted.

To address this issue, each of the PV subcells in the PV cells described herein, including the PV subcell formed in the compliant silicon substrate, will preferably have a unique band-gap energy. That is, each PV subcell in a PV cell described herein will preferably have a band-gap energy that is different from the other PV subcells in the PV cell. By designing the PV cells to include PV subcells having monotonically decreasing band-gap energies, photons having an energy level that is not absorbed and converted to electrical energy by one PV subcell in the PV device may be subsequently absorbed and converted to electrical energy by another PV subcell in the PV cell. Additionally, in the various PV cells described herein, the PV subcells will preferably be arranged in the PV cell in a descending order according to the band-gap energies of the PV subcells. That is, the PV subcell having the highest band-gap energy will preferably be located at the top of the stack, where photons first impinge on the device, the PV subcell having the next highest band-gap energy will be located below the PV subcell having the highest band-gap, and so on in descending order of band-gap energies down to the PV subcell in the compliant silicon substrate at the bottom of the PV cell.

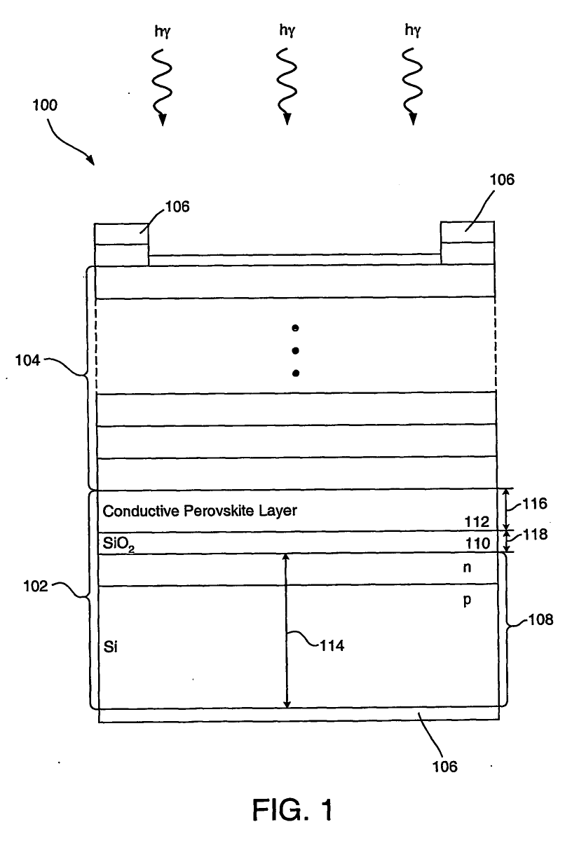

Turning now to FIG. 1, shown therein is a generalized PV cell 100 that illustrates some of the common features shared by each of the various PV cell described herein. As shown in FIG. 1, the PV cell 100 includes a compliant silicon substrate 102, upon which is monolithically grown a number of additional semiconductor layers 104. The additional layers 104 may include, for example and without limitation, PV subcells that are preferably formed of Group III-V semiconductor materials. The additional layers 104 may also include other, non-PV subcell layers, such as tunnel junction layers, Back Surface Reflector (BSR) layers, contact layers, and/or window layers. The composition and function of these additional layers will be discussed in greater detail below. As shown in FIG. 1, in addition to the compliant silicon substrate 102 and the additional semiconductor layers 104, the PV cell 100 will also preferably include various electrical contacts 106 for conducting current from the PV cell 100.

As described above, each of the layers 104 of the PV cell 100 is preferably formed of semiconductor material that is monolithically grown epitaxially on or above the compliant silicon substrate 102. In general, epitaxially grown materials attempt to mimic the crystalline structure of the material on which they are grown by matching the lattice constant of the material on which they are grown. In this respect, it is preferable in designing and fabricating monolithic, tandem PV cells to select semiconductor materials that have lattice constants that are relatively close in dimension. That is, materials with lattice constants that are said to be “matched.” This is true because lattice mismatches between adjacent layers of a PV cell may result in dislocations forming between the mismatched materials, which reduce the overall efficiency of the PV cell.

While lattice matching the Group III-V semiconductor materials in a PV cell is relatively straightforward and well known in PV cells having substrates formed from gallium arsenide (GaAs), a problem arises when trying to lattice match layers of Group III-V direct band-gap semiconductor materials to a silicon substrate. This is true, because silicon has a lattice constant that is incompatible with the lattice constants of Group III-V direct band-gap semiconductor materials. To overcome this problem, the PV cells of the present invention use a compliant substrate that flexibly accommodates the difference between the lattice constant of the Group III-V direct band-gap semiconductor materials and the lattice constant of silicon, as will now be described.

As shown in FIG. 1, the compliant silicon substrate 102 includes a base silicon layer 108, an intermediary oxide layer 110, and a conductive perovskite layer 112. The base silicon layer 108 is formed of monocrystalline silicon, and will preferably have, without limitation, a thickness 114 of between 50 to 150 μm. As described in greater detail below, in various embodiments the conductive perovskite layer 112 will preferable be composed of either a layer of n-type Strontium Titanate SrTiO₃ (STO) or a layer of Strontium Ruthenate SrRuO₃ (SRO). The conductive perovskite layer 112 will preferably have, without limitation, a thickness 116 between 30 Å to 300 Å. The intermediary oxide layer 110 is preferably formed of silicon dioxide (SiO₂₋ₓ). Henceforth, wherever SiO₂ is used it will be understood to include SiO₂₋ₓ. As will be appreciated by those skilled in the art, the intermediary oxide layer 110 will typically be formed as a result, or byproduct, of forming the conductive perovskite layer 112 on the base silicon layer 108. The precise thickness 118 of the intermediary oxide layer 110 may vary, but will generally and preferably be from between 5 Å and 12 Å.

In one embodiment of the invention, the compliant silicon substrate 102 is formed by epitaxially growing the conductive perovskite layer 112 on the base silicon layer 108. The epitaxial growth of the conductive perovskite layer 112 on the base silicon layer 108 may be accomplished in a number of ways known in the art. For example, and without limitation, the conductive perovskite layer 112 may be grown on the base silicon layer 108 with Chemical Vapor Deposition (CVD), Molecular Beam Epitaxy (MBE), or Metalorganic Chemical Vapor Deposition (MOCVD), etc. As described above, the intermediary oxide layer 110 may be formed as a result or byproduct of forming the conductive perovskite layer 112 on the base silicon layer 108.

The lattice constant of the conductive perovskite layer 112 is, in essence, relaxed as a result of the formed intermediary SiO₂ layer 110, which is amorphous (glassy). That is, the flexibility of the lattice constant of the amorphous SiO₂ layer 110 decouples the relatively thick base silicon layer 108 from constraining the lattice of the relatively thin conductive perovskite layer 112, thus allowing the conductive perovskite layer 112 to accommodate itself to the lattice of the relatively thick epitaxial layers of Group III-V direct band-gap semiconductor materials that are grown on the compliant silicon substrate 102. In general, the compliant silicon substrate 102 of the present invention accommodates layers of Group III-V semiconductor materials having lattice constants from 5.4 Å to 5.7 Å.

Generally, the preparation of compliant silicon substrates in relation to PV cells may be more fully understood with reference to: “Solar Cells: Operating Principles, Technology and System Applications,” Martin Green, Prentice-Hall, N.J. 1982; “Photovoltaic Materials,” Richard Bube, Imperial College Press, 1998. Preparation of compliant substrates for use in accordance with the present invention may be more fully understood with reference to: “Interface Characterization of High Quality Strontium Titanate (SrTiO₃) Films on Silicon (Si) Substrates Grown by Molecular Beam Epitaxy”. J. Ramdani, R. Droopad, et. al., Applied Surface Science, 159-160 (2000) 127-133; “Epitaxial Oxide Thin Films on Silicon”. Z. Tu, J. Ramdani, et al., J. Vac. Sci. Technol. B 18(4), (2000) 2139; “Epitaxial Oxides on Silicon Grown by Molecular Beam Epitaxy”. Ravi Droopad, Zayi Yu, Jamal Ramdani, et al., J. Crystalline Growth 227-228 (2001) 936; and “Plasticity and Inverse Brittle-To-Ductile Transition in Strontium Titonate”. P. Gumbsch, S. Taeri-Baghbadrani, et al., Phys. Rev. Lett. 87 (2001) 085505-1. Each of the above references is incorporated by reference in its entirety.

One problem associated with the use of typical compliant substrates using SiO₂ layers and perovskite layers (such as Strontium Titanate (STO)) grown on a base silicon layer is that the perovskite layer/SiO₂ layers function as insulators, preventing the flow of charge carriers to and/or from the active silicon substrate. To overcome this problem, the present invention uses a perovskite layer that is either doped, or that is itself conductive, to facilitate the conduction of charge carriers, as will now be described.

In one embodiment of the present invention the conductive perovskite layer 112 comprises n-type perovskite layer, such as an n-type STO. In the case where the conductive perovskite layer 112 comprises STO (SrTiO₃), the electron doping of STO may be achieved by substituting lanthanum (La) into the Strontium (Sr) sublattice (Sr₁₋ₓLaₓTiO₃, where x can range from 0 to 1). Alternatively, the electron doping of STO may be achieved by substituting niobium (Nb⁵⁺) or antimony (Sb⁵⁺) into the titanium (Ti⁴⁺) sublattice (SrTi₁₋ₓNbₓO₃, where x can range from 0 to 1). In yet another alternative, the electron doping of STO may be achieved by creating vacancies into the oxygen (O) sublattice (SrTiO_{3-δ}, where δ can range from 0 to 0.3. In an alternative to electron doped STO, the conductive perovskite layer 112 may be formed of Strontium Ruthenate (SRO). Since SRO is itself a conductor, doping of the SRO is not required to form the conductive perovskite layer from SRO.

With respect to the conductivity of the intermediary oxide layer 110, as is known, SiO₂ is an electrical insulator. However, as the intermediary oxide layer 110 is typically very thin, for example and without limitation, between 5 and 12 Å, electrons in the conduction band of 108 or 112, adjacent to the intermediary oxide layer 110, will tunnel through the intermediary oxide layer 110. As neither the conductive perovskite layer 112, nor the intermediary oxide layer 110, significantly impede the flow of charge carriers between the compliant substrate 102 and the other layers 104 of the PV cell, an active PV cell may formed in the base silicon layer 108 that is electrically connected in series with PV cells formed in the other layers 104 of the PV cell.

The particular Group III-V direct band-gap semiconductor materials used to fabricate the various layers 104 of the present invention will preferably be selected, among other things, based on their intrinsic photocurrent/photovoltage characteristics. Additionally, each particular Group III-V direct band-gap semiconductor material is preferably chosen for its target band-gap energy and its lattice matching capability with the compliant substrate, or adjacent semiconductor material. For example, the Group III-V direct band-gap semiconductor materials will preferably have direct band-gap energies of 1.4 to 2.3 eV. Regardless of the particular band-gap energies of the selected Group III-V direct band-gap semiconductors, the semiconductor layers must be lattice accommodated or matched to the adjacent layer material. Note also that Group III-V semiconductor material will preferably be applied or grown very uniformly on the conductive perovskite oxide layer 112. To accomplish this uniformity, the conductive perovskite oxide layer may be pre-treated with a thin film of surfactant before growth of the Group III-V semiconductor material on the conductive perovskite oxide layer 112.

The intrinsic properties of the Group III-V semiconductor materials used in forming the additional layers 104 of the PV cell 100 may be modified through various doping and thickness schemes to achieve desirable operational characteristics. For example, each PV subcell formed in the additional layers 104 in the PV cell 100 will preferably be composed of an emitter layer and a base layer, each layer being derived by doping the material chosen for that particular PV subcell, so as to form a junction within the PV subcell (e.g., n/p, p/n, p++/n++ layers). In general, the thickness of emitter layers of the PV subcells in the PV cell 100 will preferable be, without limitation, from about 0.01 μm to about 1 μm. Additionally, the emitter layers will preferable, without limitation, have doping levels of about 10¹⁷ cm⁻³ to about 10²⁰ cm⁻³. The thickness of the base layer of the PV subcells in the PV cell 100 will preferably be, without limitation, from about 0.1 μm to about 10 μm. The base layers will preferable, without limitation, have doping levels of about 10¹⁶ cm⁻³ to about 10¹⁸ cm⁻³. Doping and thickness schemes for semiconductor materials are well known within the art. Note that doping schemes may further be utilized to form interfaces between adjacent layers within the PV cell 100, such as tunnel junction layers.

The various PV subcells of the PV cell 100, including the PV subcell formed in the compliant substrate 102 are interconnected serially with each other via series connection layers. Furthermore, the various PV subcells of the PV cell 100 will preferably be current matched to increase photocurrent levels within the PV device 100. Current matching may be controlled during fabrication of the PV cell 100 by selecting and controlling the relative band-gap energy of the various semiconductor materials used to form each PV subcell, and/or by altering the thickness of each PV subcell to modify its photogenerated current. Current flow of each PV subcell in the PV cell 100 is preferably matched at the maximum power level of the PV cell or at the short-circuit current level of the PV cell, and more preferably at a point between these levels for improved energy conversion efficiency. Series connection of the subcells in a PV cell is preferably accomplished by inserting a low-resistivity tunnel junction layer between any two current matched PV subcells to improve current flow. The tunnel junction layer may take a number of forms to provide a thin layer of material that allows current to pass between the PV subcells, without generating a voltage drop large enough to significantly decrease the conversion efficiency of the PV cell, and while preserving lattice matching between the adjacent PV subcell semiconductor materials. The fabrication and design of tunnel junctions is well known in the art. Note also that other methods of producing series connections for use with the present invention are known in the art and are considered to be within the scope of the present invention.

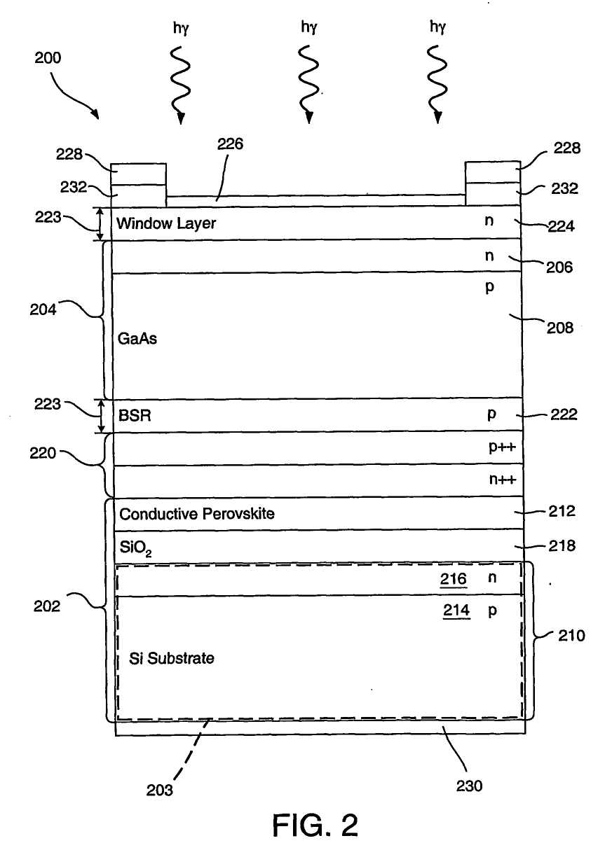

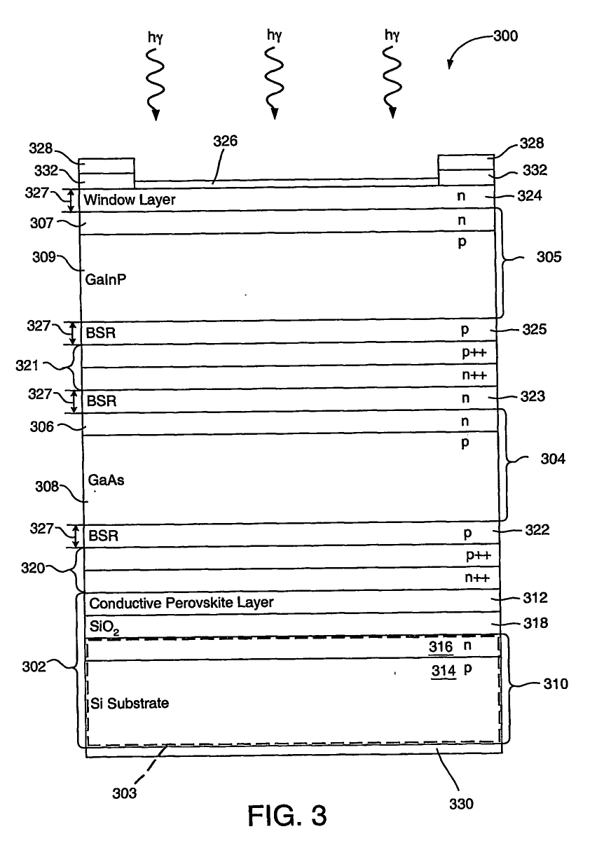

FIGS. 2 and 3 illustrate specific PV cells in accordance with the present invention. It should be understood that the various concepts, features, and techniques that have just been described with respect to the PV cell 100 of FIG. 1 are applicable to each of the PV devices shown in FIGS. 2-3. The PV cells illustrated in FIGS. 2-3 have been simplified so that a basic understanding of the main concepts and features of these PV cells may more easily be understood. Furthermore, the dimensions and proportions of the PV cells illustrated in FIGS. 2-3 have been exaggerated for clarity, as will be readily understood by persons skilled in the art.

FIG. 2 illustrates a two subcell, tandem monolithic photovoltaic (PV) cell 200 in accordance with a first embodiment of the present invention. As shown, the PV cell 200 generally includes, a compliant silicon substrate 202, having formed therein a first PV subcell 203, and a second PV subcell 204. Both the first PV subcell 203 and a second PV subcell 204 are operable to produce a photocurrent when photons having appropriate energy levels impinge on them.

The compliant silicon substrate 202 is generally composed of a base silicon layer 210 and a conductive perovskite layer 212. The base silicon layer 210 is composed substantially of silicon that has been doped (e.g., impurities added that accept or donate electrons) to form appropriate p-type 214 and n-type 216 regions of the first PV subcell 203. The base silicon layer 210 preferably has a band-gap energy of approximately 1.1 eV. In one embodiment, the conductive perovskite layer 212 comprises Strontium Titanate (SrTiO₃) that has been electron doped, as described above with respect to PV device 100. In another embodiment, the conductive perovskite layer 212 comprises Strontium Ruthenate (SRO). Between the base silicon layer 210 and conductive perovskite oxide layer 212, a layer of SiO₂ 218 is formed.

The second PV subcell 204 is composed substantially of Gallium Arsenide (GaAs) that has been doped (e.g., impurities added that accept or donate electrons) to form appropriate n-type 206 and p-type 208 regions in the PV subcell. In this embodiment, the GaAs of the second PV subcell 204 preferably has a band-gap energy of approximately 1.42 eV.

Those skilled in the art will appreciate that while the second PV subcell 204 has been described as being composed particularly of GaAs, the second PV subcell 204 may alternatively be composed of other Group III-V materials. For example, and without limitation, in a first alternate embodiment of the PV cell 200, rather than being composed of GaAs, the second PV subcell 204 may be composed of GaAsP (GaAsₓP₁₋ₓ , where x can range from 0 to 1). In this first alternative embodiment of the PV cell 200, the GaAsP preferably has a band-gap energy of approximately 1.4 to 1.9 eV. In a second alternate embodiment of the PV cell 200, the second PV subcell 204 may be composed of GaInP (GaₓIn₁₋ₓP, where x can range from 0 to 1). In this second alternative embodiment of the PV cell 200, the GaInP preferably has a band-gap energy of approximately 1.9 to 2.2 eV. Those skilled in the art will appreciate various other changes and modifications may be made to the composition of the second PV subcell 204 that are well within the scope of the invention.

To facilitate photocurrent flow between the first PV subcell 203 and the second PV subcell 204, the PV cell 200 may include a low-resistivity tunnel junction 220. The tunnel junction 220 may take a number of forms and materials to provide an appropriate layer thickness that allows photocurrent to pass between the first PV subcell 203 and the second PV subcell 204 without generating a voltage drop large enough to significantly decrease the conversion efficiency of the PV cell 200, while preserving lattice-matching between the compliant silicon substrate 202 and the second PV cell 204.

As shown in FIG. 2, the first PV subcell 203 formed in the compliant silicon substrate 202 includes p-type 214 and n-type 216 regions, with the n-type region being adjacent to the SiO₂ layer 218. However, it should be understood that the first PV subcell 203 may be formed in the compliant silicon substrate 202 with the p-type region being adjacent to the SiO₂ layer 218. That is, the positions of the p-type 214 and n-type 216 regions in the first PV subcell 203 may be switched or reversed. In such a case, the tunnel junction 220, shown in FIG. 2 as being located between the compliant silicon substrate 202 and the second PV subcell 204 (or the BSR layer 222), would preferably be moved from its position shown in FIG. 2 to a position between the first PV subcell 203 and the SiO₂ layer 218. Likewise, the p-type and n-type regions of all other subcells and tunnel junction layers in the PV cell 200 would also be switched.

As shown in FIG. 2, in one embodiment, the PV cell 200 may include a back-surface reflector (BSR) layer 222 between the tunnel junction 220 and the second PV subcell 204 and/or a window layer 224 on top of the second PV subcell 204. As is known in the art, BSR and window layers prevent surface or interface recombination within or among a PV subcell by preventing minority carriers (i.e., orphan carriers) from recombining within the PV subcells. Recombination of minority carriers at a PV subcell surface creates losses in photocurrent and photovoltage, thereby reducing the energy conversion efficiency of the PV cell. As such, BSR and window layers introduce an electronic barrier to minority carriers while acting as an electrical reflector for the PV subcell. BSR and window layers are generally composed of low resistivity materials, such as, without limitation, GaₓIn₁₋ₓP, AlₓIn₁₋ₓP, AlₓGa_{y}In_{1-x-y}P, etc., and are generally from about 0.01 μm to about 0.1 μm in thickness 223, with doping levels from about 10¹⁶ cm⁻³ to about 10²⁰ cm⁻³. In one embodiment, and as shown in FIG. 2, the second PV subcell 204 is bracketed by the BSR layer 222 and the window layer 224.

In one embodiment, the PV cell 200 optionally includes an anti-reflective coating 226 on top of the window layer 224 to reduce the unwanted reflection of photons away from the PV cell 200. In one embodiment, the surface of the window layer 224 may be textured prior to applying the anti-reflective coating 226. The textured surface will force the photons to strike the surface of the solar cells more than once, thus preventing the photons from leaving the surface of the PV device and increasing the probability that the photon will enter the PV cell 200.

As shown in FIG. 2, the PV cell 200 preferably includes a grid electrical contact 228 on the top surface of the PV cell 200 cell and an electrical back contact 230 on the bottom of the PV cell 200 for conducting current away from and into the PV cell 200. Additionally, to facilitate ohmic contacts, a contact layer 232 may be placed between the grid electrical contact 228 and the window layer 224.

As will be appreciated by those skilled in the art, the combination of materials that make-up the PV cell 200 will preferably be lattice matched and have the appropriate band-gap energies to efficiently function in the photoconversion of sunlight to electrical energy. As such, the lattice constants of the compliant silicon substrate 202, the second PV subcell 204, the tunnel junction 220, the BSR layer 222 and the window layer 224 will preferably be substantially lattice matched.

Turning now to FIG. 3, illustrated therein is a three-PV subcell, tandem monolithic PV cell 300 in accordance with a second embodiment of the present invention. As shown, the PV cell 300 generally includes, a compliant silicon substrate 302, having formed therein a first PV subcell 303, a second PV subcell 304, and a third PV subcell 305. The first PV subcell 303, the second PV subcell 304, and the third PV subcell 305 are all preferably operable to produce a photocurrent when photons having appropriate energy levels impinge on them.

The compliant silicon substrate 302 is generally composed of a base silicon layer 310, an intermediary oxide layer 318, and a conductive perovskite layer 312. The base silicon layer 310 is composed substantially of silicon that has been doped (e.g., impurities added that accept or donate electrons) to form appropriate p-type 314 and n-type 316 regions of the first PV subcell 303. The base silicon layer 310 preferably has a band-gap energy of approximately 1.1 eV. In one embodiment, the conductive perovskite layer 312 comprises Strontium Titanate (SrTiO₃) that has been electron doped, as described above with respect to PV device 100. In another embodiment, the conductive perovskite layer 312 comprises Strontium Ruthenate (SRO). Between the base silicon layer 310 and conductive perovskite oxide layer 312, a layer of SiO₂ 318 is formed.

The second PV subcell 304 is composed substantially of Gallium Arsenide (GaAs) that has been doped (e.g., impurities added that accept or donate electrons) to form appropriate n-type 306 and p-type 308 regions in the PV cell. In this embodiment, the GaAs of the second PV subcell 304 preferably has a band-gap energy of approximately 1.42 eV.

Those skilled in the art will appreciate that while the second PV subcell 304 has been described as being composed particularly of GaAs, the second PV subcell 304 may alternatively be composed of other Group III-V materials. For example, and without limitation, in a first alternate embodiment of the PV cell 300, rather than being composed of GaAs, the second PV cell 304 may be composed of GaAsP (GaAsₓP₁₋ₓ, where x can range from 0 to 1). In this first alternative embodiment of the PV cell 300, the GaAsP preferably has a band-gap energy of approximately 1.5 to 1.9 eV. Those skilled in the art will appreciate various other changes and modifications may be made to the composition of the second PV subcell 304 that are well within the scope of the invention.

The third PV subcell 305 is composed substantially of GaInP (GaₓIn₁₋ₓP, where x can range from 0 to 1) that has been doped (e.g., impurities added that accept or donate electrons) to form appropriate n-type 307 and p-type 309 regions in the PV subcell 305. In this embodiment, the GaInP of the third PV subcell 304 preferably has a band-gap energy of approximately 1.9 eV. Those skilled in the art will appreciate that while the third PV subcell 305 has been described as being composed particularly of GaInP, the third PV subcell 305 may alternatively be composed of other Group III-V materials.

To facilitate photocurrent flow between the first PV subcell 303 and the second PV subcell 304, and/or between the second PV subcell 304 and the third PV subcell 305, the PV cell 300 may include low-resistivity tunnel junctions situated between these subcells. For example, as shown in FIG. 3, a first tunnel junction 320 is located between the compliant silicon substrate 302, having the first PV subcell 303 therein, and the second PV subcell 304. Similarly, a second tunnel junction 321 is located between the second PV subcell 304 and the third PV subcell 305. The tunnel junctions 320 and 321 may take a number of forms and comprise a number of different materials to provide an appropriate layer thickness that allows photocurrent to pass between the various PV subcells in the PV cell 300 without generating a voltage drop large enough to significantly decrease the conversion efficiency of the PV cell 300, while preserving lattice-matching between the compliant silicon substrate 302 and the other PV subcells of the PV cell 300.

As shown in FIG. 3, the first PV subcell 303 formed in the compliant silicon substrate 302 includes p-type 314 and n-type 316 regions, with the n-type region being adjacent to the SiO₂ layer 318. However, it should be understood that the first PV subcell 303 may be formed in the compliant silicon substrate 302 with the p-type region being adjacent to the SiO₂ layer 318. That is, the positions of the p-type 314 and n-type 316 regions in the first PV subcell 303 may be switched or reversed. In such a case, the tunnel junction 320, shown in FIG. 3 as being located between the compliant silicon substrate 302 and the second PV subcell 304 (or the BSR layer 322), would preferably be moved from its position shown in FIG. 3 to a position between the first PV subcell 303 and the SiO₂ layer 318. Likewise, the p-type and n-type regions of all other subcells and tunnel junction layers in the PV cell 300 would also be switched.

As shown in FIG. 3, in one embodiment, the PV cell 300 may include a back-surface reflector (OSR) layer 322 between the tunnel junction 320 and the second PV subcell 304, as well as a BSR layer 323 between the second PV subcell 304 and the tunnel junction 321, and yet another BSR layer 325 between the tunnel junction 321 and the third PV subcell 305. Additionally, a window layer 324 may be included on top of the third PV subcell 305. As described above, BSR and window layers introduce an electronic barrier to minority carriers while acting as an electrical reflector for the PV subcells. The BSR and window layers are generally composed of low resistivity materials, such as, without limitation, GaₓIn₁₋ₓP, AlₓIn₁₋ₓP, AlₓGa_{y}In_{1-x-y}P, etc., and are generally from about 0.01 μm to about 0.1 μm in thickness 327, with doping levels from about 10¹⁶ cm⁻³ to about 10²⁰ cm⁻³.

In one embodiment, the PV cell 300 optionally includes an anti-reflective coating 326 on top of the window layer 324 to reduce the unwanted reflection of photons away from the PV cell 300. Additionally, the surface of the window layer 324 may be textured prior to applying the anti-reflective coating 326.

As shown in FIG. 3, the PV cell 300 preferably includes a grid electrical contact 328 on the top surface of the PV cell 300 cell and an electrical back contact 330 on the bottom of the PV cell 300 for conducting current away from and into the PV cell 300. Additionally, a contact layer 332 may be placed between the grid electrical contact 328 and the window layer 324.

As will be appreciated by those skilled in the art, the combination of materials that make-up the PV cell 300 will preferably be lattice matched and have the appropriate band-gap energies to efficiently function in the photoconversion of sunlight to electrical energy. As such, the lattice constants of the compliant silicon substrate 302, the second PV subcell 304, the third PV subcell 305, the tunnel junctions 320 and 321, the BSR layers 322, 323 and 325 and the window layer 324 will preferably be substantially lattice matched.

As so far described, the various embodiments of the present invention have included a conductive pervoskite layer, such as an n-type doped STO. While the use of an n-type doped STO layer is preferred, in alternatives to each of the embodiment so far described, an undoped STO layer may be used, as will be described.

As is known, the band gaps of the materials (Si/SiO₂)STO) constituting the compliant substrate are approximately 1.1 eV, 9 eV, and 3.25 eV, respectively. The conduction band and valence band offsets between Si and the SiO₂ are several eV in magnitude. The conduction band offset between Si and STO is negligibly small, something less than about 100 meV. As such, most of the band offset between Si and STO is between the valence bands. In the case where a PV subcell is fabricated in the compliant substrate that is connected monolithically in tandem to III-V solar cells grown epitaxially on the compliant substrate, as described above, if the thickness of the SiO₂ layer is kept between approximately 5 Å and 12 Å and the thickness of the STO layer is between approximately 30 Å and 300 Å, electrons in the conduction band of Si will tunnel through the SiO₂ layer and drift across the STO layer under solar cell device operating conditions. Thus, even if the STO layer is undoped, electrons injected into the conduction band of the STO layer will ensure minority carrier transport with a minimal voltage drop across this thin STO layer. However, as described, it is preferable to use an n-type doped STO layer to ensure that just prior to device turn-on, the voltage dropped across the STO layer is minimal.

It will be clear that the present invention is well adapted to attain the ends and advantages mentioned as well as those inherent therein. While preferred embodiments have been described for purposes of this disclosure, various changes and modifications may be made which are well within the scope of the invention. Numerous changes may be made which will readily suggest themselves to those skilled in the art and which are encompassed in the spirit of the invention disclosed herein and as defined in the appended claims. All publications cited herein are hereby incorporated by reference.

1. A monolithic, tandem photovoltaic (PV) cell comprising:
a compliant silicon substrate including a base silicon layer having a first PV subcell formed therein, a conductive perovskite layer, and a SiO₂ layer interposed between the conductive perovskite layer and the base silicon layer;
a second PV subcell positioned above the compliant silicon substrate; and
electrical contacts operably connected to the PV cell to conduct current to and from the PV cell.

2. A monolithic, tandem PV cell as defined in claim 1, wherein the conductive perovskite layer comprises electron doped strontium titanate.

3. A monolithic, tandem PV cell as defined in claim 1, wherein the conductive perovskite layer comprises strontium ruthenate.

4. A monolithic, tandem PV cell as defined in claim 1, wherein the conductive perovskite layer comprises Sr₁₋ₓLaₓTiO₃.

5. A monolithic, tandem PV cell as defined in claim 1, wherein the conductive perovskite layer comprises SrTi₁₋ₓNbₓO₃.

6. A monolithic, tandem PV cell as defined in claim 1, wherein the conductive perovskite layer comprises SrTiO_{3-δ}, where 0<8 δ<0.3.

7. A monolithic, tandem PV cell as defined in claim 1, wherein the second PV subcell is formed of a group III-V direct band-gap semiconductor material.

8. A monolithic, tandem PV cell as defined in claim 7, wherein the group III-V direct band-gap semiconductor material comprises GaAsₓP₁₋ₓ.

9. A monolithic, tandem PV cell as defined in claim 7, wherein the group III-V direct band-gap semiconductor material comprises GaₓIn₁₋ₓP.

10. A monolithic, tandem PV cell as defined in claim 7, wherein the group III-V direct band-gap semiconductor material comprises GaAs.

11. A monolithic, tandem PV cell as defined in claim 1, wherein the conductive perovslite layer comprises electron doped strontium titanate and the second PV subcell is formed of a group III-V direct band-gap semiconductor material.

12. A monolithic, tandem PV cell as defined in claim 1, wherein the conductive perovskite layer comprises strontium ruthenate and the second PV subcell is formed of a group III-V direct band-gap semiconductor material.

13. A monolithic, tandem PV cell as defined in claim 1, further comprising an electrically conductive interconnection layer interposed between the compliant silicon substrate and the second subcell.

14. A monolithic, tandem PV cell as defined in claim 13, further comprising a back surface reflector (BSR) layer interposed between the interconnection layer and the second subcell.

15. A monolithic, tandem PV cell as defined in claim 14, wherein the BSR layer is formed of a material selected from a group consisting of GaₓIn₁₋ₓP, AlₓIn₁₋ₓP, and AlₓGa_{y}In_{1-x-y}P.

16. A monolithic, tandem PV cell as defined in claim 15, wherein the BSR layer has a thickness of between 0.01 μm and 0.1 μm.

17. A monolithic, tandem PV cell as defined in claim 1, wherein the conductive perovskite layer has a thickness of 30 Å to 300 Å.

18. A monolithic, tandem PV cell as defined in claim 17, wherein the SiO₂ layer has a thickness of between 5 Å and 12 Å.

19. A monolithic, tandem PV cell as defined in claim 18, wherein the base silicon layer has a thickness of between 50 to 150 μm.

20. A multi-junction, monolithic, photovoltaic (PV) cell configured for producing a photocurrent when exposed to photons, comprising:
a compliant substrate including a base layer having a first PV subcell formed therein, a conductive perovskite layer, and an oxide layer interposed between the conductive perovskite layer and the base layer;
a second PV subcell monolithically formed above the compliant silicon substrate;
an electrically conductive interconnection layer interposed between the compliant substrate and the second PV subcell; and
electrical contacts operably connected to the PV cell to conduct current to and from the PV cell.

21. A multi-unction, monolithic, PV cell as defined in claim 20, wherein the base layer is formed of monocrystalline silicon.

22. A multi-junction, monolithic, PV cell as defined in claim 21, wherein the oxide layer is formed of SiO₂.

23. A multi-junction, monolithic, PV cell as defined in claim 20, wherein the conductive perovskite layer comprises electron doped strontium titanate.

24. A multi-junction, monolithic, PV cell as defined in claim 20, wherein the conductive perovskite layer comprises Sr₁₋ₓLaₓTiO₃.

25. A multi-junction, monolithic, PV cell as defined in claim 20, wherein the conductive perovskite layer comprises SrTi₁₋ₓNbₓO₃.

26. A multi-junction, monolithic, PV cell as defined in claim 20, wherein the conductive perovskite layer comprises SrTiO_{3-δ}.

27. A multi-unction, monolithic, PV cell as defined in claim 20, wherein the second PV subcell is fabricated from a group III-V direct band-gap semiconductor material.

28. A multi-junction, monolithic, PV cell as defined in claim 27, wherein the group III-V direct band-gap semiconductor material comprises GaAsₓP₁₋ₓ.

29. A multi-junction, monolithic, PV cell as defined in claim 27, wherein the group III-V direct band-gap semiconductor material comprises GaₓIn₁₋ₓP.

30. A multi-junction, monolithic, PV cell as defined in claim 27, wherein the group III-V direct band-gap semiconductor material comprises GaAs.

31. A multi-PV subcell, monolithic, photovoltaic (PV) cell configured for producing a photocurrent when exposed to photons, comprising:
a compliant silicon substrate including a base silicon layer having a first PV subcell formed therein, a conductive perovskite layer, and an oxide layer interposed between the conductive perovskite layer and the base silicon layer;
a second PV subcell formed of a group III-V direct band-gap semiconductor material; and
a third PV subcell formed of a group III-V direct band-gap semiconductor material.

32. A multi-PV subcell, monolithic, PV cell as defined in claim 31, wherein the third PV subcell is formed of GaₓIn₁₋ₓP.

33. A multi-PV subcell, monolithic, PV cell as defined in claim 32, wherein the second PV subcell is formed of GaAsₓP₁₋ₓ.

34. A multi-PV subcell, monolithic, PV cell as defined in claim 32, wherein the second PV subcell is formed of GaAs.

35. A multi-PV subcell, monolithic, PV cell as defined in claim 31, further comprising a first electrically conductive interconnection layer interposed between the compliant silicon substrate and the second PV subcell and a second electrically conductive interconnection layer interposed between the second PV subcell and the third PV cell.

36. A multi-PV subcell, monolithic, PV cell as defined in claim 35, further comprising a first back surface reflector layer interposed between the first electrically conductive interconnection layer and the second PV subcell.

37. A multi-PV subcell, monolithic, PV cell as defined in claim 36, further comprising a second back surface reflector layer interposed between the second electrically conductive interconnection layer and the third PV subcell.

38. A multi-PV subcell, monolithic, PV cell as defined in claim 36, wherein the first electrically conductive interconnection layer and the second electrically conductive interconnection layer comprise tunnel junctions.

39. A multi-PV subcell, monolithic, PV cell as defined in claim 31, wherein the conductive perovskite layer comprises electron doped strontium titanate.

40. A multi-PV subcell, monolithic, PV cell as defined in claim 39, wherein the conductive perovskite layer comprises Sr₁₋ₓLaₓTiO₃.

41. A multi-PV subcell, monolithic, PV cell as defined in claim 39, wherein the conductive perovskite layer comprises SrTi₁₋ₓNbₓO₃.

42. A multi-PV subcell, monolithic, PV cell as defined in claim 31, wherein the conductive perovskite layer comprises SrTiO_{3-δ}.

43. A multi-PV subcell, monolithic, PV cell as defined in claim 31, wherein the conductive perovskite layer comprises strontium ruthenate.

44. A method of forming a multi-junction, monolithic, photovoltaic (PV) cell, comprising:
forming n-type and p-type regions in a base silicon layer to create a first PV subcell within the base silicon layer;
forming a conductive perovskite layer above the base silicon layer;
forming an oxide layer between the conductive perovskite layer and the base silicon layer; and
forming a second PV subcell of a group III-V direct band-gap semiconductor material above the conductive perovskite layer.

45. A method of forming a multi-junction, monolithic, PV cell as defined in claim 44, further comprising forming a third PV subcell of a group III-V direct band-gap semiconductor material above the second PV subcell.

46. A method of forming a multi-junction, monolithic, PV cell as defined in claim 44, further comprising forming a first electrically conductive interconnection layer between the conductive perovskite layer and the second PV subcell.

47. A method of forming a multi-junction, monolithic, PV cell as defined in claim 46, further comprising forming a first back surface reflector layer between the first electrically conductive interconnection layer and the second PV subcell.

48. A method of forming a multi-junction, monolithic, PV cell as defined in claim 45, further comprising forming a first electrically conductive interconnection layer between the conductive perovskite layer and the second PV subcell and a second electrically conductive interconnection layer between the second PV subcell and the third PV subcell.

49. A method of forming a multi-junction, monolithic, PV cell as defined in claim 48, further comprising forming a first back surface reflector (BSR) layer between the first electrically conductive interconnection layer and the second PV subcell, forming a second BSR layer between the second PV subcell and the second electrically conductive interconnection layer, and forming a third BSR layer between the second electrically conductive interconnection layer and the third PV subcell.

50. A method of forming a multi-junction, monolithic, PV cell as defined in claim 49, further comprising forming a window layer above the third PV subcell.

51. A method of forming a multi-junction, monolithic, PV cell as defined in claim 44, wherein the conductive perovskite layer is formed of Sr₁₋ₓ LaₓTiO₃.

52. A method of forming a multi-junction, monolithic, PV cell as defined in claim 44, wherein the conductive perovskite layer is formed of SrTi₁₋ₓNbₓO₃.

53. A method of forming a multi-junction, monolithic, PV cell as defined in claim 44, wherein the conductive perovskite layer is formed of SrTiO_{3-δ}.

54. A method of forming a multi-junction, monolithic, PV cell as defined in claim 44, wherein the conductive perovskite layer is formed of strontium ruthenate.

55. A method of forming a multi-junction, monolithic, PV cell as defined in claim 44, wherein the second PV subcell is formed of GaAsₓP₁₋ₓ.

56. A method of forming a multi-junction, monolithic, PV cell as defined in claim 44, wherein the second PV subcell is formed of GaₓIn₁₋ₓP.

57. A method of forming a multi-junction, monolithic, PV cell as defined in claim 44, wherein the second PV subcell is formed of GaAs.

58. A method of forming a multi-junction, monolithic, PV cell as defined in claim 45, wherein the third PV subcell is formed of GaₓIn₁₋ₓP.

59. A method of forming a multi-unction, monolithic, PV cell as defined in claim 58, wherein the second PV subcell is formed of GaAs.

60. A method of forming a multi-junction, monolithic, PV cell as defined in claim 58, wherein the second PV subcell is formed of GaAsₓP₁₋ₓ.

61. A monolithic, tandem photovoltaic (PV) cell comprising:
a compliant silicon substrate including a base silicon layer having a first PV subcell formed therein, a perovskite layer, and a SiO₂ layer having a thickness of between 5 Å and 12 Å interposed between the conductive perovskite layer and the base silicon layer;
a second PV subcell positioned above the compliant silicon substrate; and
electrical contacts operably connected to the PV cell to conduct current to and from the PV cell.

62. A multi-PV subcell, monolithic, PV cell as defined in claim 61, wherein the perovskite layer is between 30 Å and 300 Å.

63. A multi-PV subcell, monolithic, PV cell as defined in claim 62, wherein the perovskite layer comprises strontium titanate.
